(19) United States
(12) Patent Application Publication
(10) Pub. No.: US 2015/0243826 A1
(43) Pub. Date: Aug. 27, 2015

(54) TUNABLE HETEROJUNCTION FOR MULTIFUNCTIONAL ELECTRONICS AND PHOTOVOLTAICS

(71) Applicant: Northeastern University, Boston, MA (US)

(72) Inventors: Xiaohong An, Boston, MA (US); Fangze Liu, Boston, MA (US); Swastik Kar, Boston, MA (US)

(21) Appl. No.: 14/423,636

(22) PCT Filed: Aug. 27, 2013
(86) PCT No.: PCT/US13/56854

§ 371 Date: Feb. 24, 2015

Related U.S. Application Data
(60) Provisional application No. 61/693,822, filed on Aug. 28, 2012.

(51) Int. Cl. H01L 31/112; H01L 31/18; H01L 31/028

(52) U.S. Cl. CPC H01L 31/112; H01L 31/028; H01L 31/1804

(57) ABSTRACT

Provided in one embodiment is a method for operating a photodiode device, which device comprises: at least one layer of an n-doped semiconductor material; two portions of a dielectric material separately disposed over separate regions of the at least one layer of the n-doped semiconductor material; at least one monolayer of a carbon-based material disposed between the two portions of dielectric material and over the at least one layer of the n-doped semiconductor material; two terminal electrodes, each electrode disposed in electrical communication with a respective one of the portions of dielectric material; and a gate electrode in electrical communication with the at least one layer of the n-doped semiconductor material. The method comprises: applying a voltage across the gate electrode and one of the two terminal electrodes; and exposing the photodiode device to electromagnetic radiation.

### RELATED APPLICATION

This application claims priority from U.S. Provisional Application Ser. No. 61/693,822, filed Aug. 28, 2012, which is hereby incorporated by reference in its entirety.

### STATEMENT REGARDING FEDERALLY SPONSORED RESEARCH

This invention was made with government support under award No: ECCS-1202376, awarded by the National Science Foundation (NSF). The United States government has certain rights in this invention.

### BACKGROUND

A majority of photodetectors employ semiconductor heterojunctions in a variety of operational configurations over a wide spectral range. While GaAs-, GaN-, AlGaN-, SiC- and Si-based devices are popular UV detectors, Si, Ge, InGaAs, etc. are compatible with detection in the visible-NIR regions. Pyroelectric and bolometric devices are more common in the mid-and far IR wavelengths.

An important parameter for photodetection is the photocurrent responsivity R(λ), i.e. photocurrent(Iₚₕ)/incident power(P), which may be closely related to the external quantum efficiency (R(λ)=(eλ/hc)×QE). The responsivities of pre-existing photodetectors range between tens to hundreds of mA/W corresponding to a QE≈10-60%. Even at 100% quantum efficiency, the responsivity is limited to R(λ)≈0.4-1.2 A/W (for λ=500-1500 nm), and techniques such as waveguide coupling may result in responsivities above 1 A/W in some devices. The conventional approach to accomplish higher responsivities is to use gain mechanisms, e.g. avalanche breakdown in high reverse-bias operation. Commercially available avalanche photodiodes (APD), operating near the reverse breakdown voltage may achieve quantum gains (QG) of 10-100 (R˜few tens of A/W), and with QG=10⁶-10⁸ by operating in a “Geiger mode” (i.e. at reverse-bias values beyond breakdown), a method used for single photon detection. However, these devices often demand extremely high operating voltages (hundreds of volts), are noisy, and unstable against high-speed operations. In addition, they demand complicated fabrication steps and measurement/control instrumentation, making them expensive. Other techniques, such as photomultiplier tubes may achieve even higher gain. However, apart from their high costs, complex architectures, and need for complicated control electronics, these devices suffer from similar limitations of high operating voltages, noise, and bulkiness, and are currently incompatible for ultrasensitive on-chip applications. Although Multiple Exciton generation (MEG) processes, whereby a high-energy photon may excite two or more e-h pairs, may have QE values >100%, at best, they may improve the QE and responsivity only by a few factors.

### SUMMARY

In view of the foregoing, the Inventors have recognized and appreciated the advantages of a system comprising tunable heterojunction and the methods of using and making same. For example, the system may be a tunable graphene-silicon heterojunction dual-model photodetector with ultra-high responsivity and quantum gain.

Accordingly, provided in one embodiment is a method for operating a photodiode device comprising: providing a photodiode device, which device comprises: at least one layer of an n-doped semiconductor material; two portions of a dielectric material separately disposed over separate regions of the at least one layer of the n-doped semiconductor material; at least one monolayer of a carbon-based material disposed between the two portions of dielectric material and over the at least one layer of the n-doped semiconductor material; two terminal electrodes, each electrode disposed in electrical communication with a respective one of the portions of dielectric material; and a gate electrode in electrical communication with the at least one layer of the n-doped semiconductor material; applying a voltage across the gate electrode and one of the two terminal electrodes; and exposing the photodiode device to electromagnetic radiation. A measure of an electrical property of the photodiode device may provide a measure of the electromagnetic radiation incident on the photodiode device.

Provided in another embodiment is a method for operating a photodiode device comprising: providing a photodiode device, which device comprises: at least one layer of an n-doped semiconductor material; two portions of a dielectric material separately disposed over two separate regions of the at least one layer of the n-doped semiconductor material; a carbon-based material disposed between the two portions of the dielectric material and over the at least one layer of the n-doped semiconductor material; two terminal electrodes, each electrode disposed in electrical communication with a respective one of the two portions of dielectric material; and a gate electrode in electrical communication with the at least one layer of the n-doped semiconductor material; applying a voltage across the two terminal electrodes; and exposing the photodiode device to electromagnetic radiation. A measure of an electrical property of the photodiode device may provide a measure of the electromagnetic radiation incident on the photodiode device.

Provided in another embodiment is a method for operating a photodiode device comprising: providing a photodiode device, which device comprises: at least one layer of an n-doped semiconductor material; two portions of a dielectric material separately disposed over separate regions of the at least one layer of the n-doped semiconductor material; a carbon-based semiconducting material disposed between the two portions of dielectric material and over the at least one layer of the n-doped semiconductor material; two terminal electrodes, each electrode disposed in electrical communication with a respective one of the portions of dielectric material; and a gate electrode in electrical communication with the at least one layer of the n-doped semiconductor material; applying a voltage across the gate electrode and one of the two terminal electrodes; exposing the photodiode device to electromagnetic radiation; measuring an electrical property of the photodiode device to provide a measure of the electromagnetic radiation incident on the photodiode device; and applying the voltage across the two terminal electrodes if the measure of the electromagnetic radiation incident on the photodiode device falls below a predetermined threshold value.

It should be appreciated that all combinations of the foregoing concepts and additional concepts discussed in greater detail below (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. It should also be appreciated that terminology explicitly employed herein that also may appear in any disclosure incorporated by reference should be accorded a meaning most consistent with the particular concepts disclosed herein.

### BRIEF DESCRIPTION OF THE DRAWINGS

The skilled artisan will understand that the drawings primarily are for illustrative purposes and are not intended to limit the scope of the inventive subject matter described herein. The drawings are not necessarily to scale; in some instances, various aspects of the inventive subject matter disclosed herein may be shown exaggerated or enlarged in the drawings to facilitate an understanding of different features. In the drawings, like reference characters generally refer to like features (e.g., functionally similar and/or structurally similar elements).

FIG. 1 illustrates Photocurrent Responsivity (Amperes-per-Watt), which is a measure of output photo-current (in Amperes) for a given incident light power (in Watts) for graphene/Si photodetectors of various sizes and operated in two different modes in one embodiment. A transformative paradigm of on-chip photodetection—spanning more than ten decades of incident power range (dynamic range), graphene/Si heterojunction photosensing devices, switched between a photodiode mode (Mode1) and a Quantum Carrier Reinvestment (QCR) mode (Mode2) will surpass all conventional on-chip and existing graphene-based photodetectors.

FIGS. 2(a)-2(d) illustrate the different characteristics of several devices in one embodiment: (a) shows a schematic representation of the device architecture in Mode1. (b) shows a digital photograph of a 5 mm×5 mm (active area) device. (c) shows current-voltage characteristics of this device under various incident powers of a monochromatic light of wavelength=488 nm. (d) shows dark-current-subtracted photocurrent as a function of incident power for various applied device bias conditions. Inset: Linear photocurrent response tested over four orders of magnitude incident powers.

FIG. 3 illustrates the Spectral response of heterojunction device using a (3-Layer graphene sheet doped with PCA)/Silicon in one embodiment.

FIGS. 4(a)-4(d) illustrate the Mode2: The Quantum Carrier Reinvestment (QCR) method in one embodiment of Mode2: (a) shows an SEM image of an L˜50 pm device. (b) shows time-trace of photocurrent in an L=2 mm device under dark and P=352 nW incidence. (c) shows bias-dependent photocurrent in an L=5 mm graphene/Si QCR device. (d) shows applying a reverse-bias (Hybrid mode) of a few 100 mV may double the responsivity compared to zero reverse-bias Mode2 value.

FIGS. 5(a)-5(g) show voltage controllable photocurrent in graphene-Si heterojunctions in one embodiment: (a) and (b) show a schematic and a digital photograph, respectively, of a monolayer graphene (1 LG)/Si heterojunction device, with the polarity in (a) shown for forward bias. (c) shows a thermal equilibrium energy band diagram of the heterojunction in darkness, with the band profile of n-Si pinned to the charge neutrality level of its own surface states (see text); the dark Fermi level of graphene E_{f}(Gr) is also shown. (d) shows current-voltage (IV) curves of device A (area=25 mm²) under darkness and weak illumination (P=1.23 μW, λ=488 nm) showing a conventional photodiode-like behavior. (e) shows deviation of the IV curves from a conventional photodiode response as the incident light power is increased up to P=6.5 mW; the expected ideal photodiode behavior at P=6.5 mW is plotted with a red dashed line. (f) provides a schematic showing the application of a forward bias (V^{f}_{bias}) that lowers E_{f}(Gr), and reduces the number of accessible states for the injection of photoexcited holes from Si, resulting in the strongly suppressed photocurrent in forward bias seen in 1(e); the red surface on the Dirac cone of graphene denotes the holes injected from Si, and is a measure of the maximum photocurrent when the quasi Fermi level of graphene, E′_{f}(Gr) aligns with the quasi Fermi level for holes in Si, E′_{f,h}(Si). (g) shows that the application of a reverse bias (V^{f}_{bias}) raises E_{f}(Gr) and opens up a large number of accessible states that may be occupied by photoexcited holes injected from Si under illumination—this results in the unsuppressed large photocurrents under reverse bias as seen in 1(e). The external bias controls the position of the Fermi level and hence the number of photo-excited carriers that may inject from Si (i.e., the photocurrent).

FIGS. 6(a)-6(d) show the broad operational power range of a high-sensitivity 1 LG/Si tunable photodetector and photoswitch in one embodiment: (a) shows variation of the voltage responsivity obtained from the open-circuit voltage, V_{OC}, and as a function of incident power, P, in device B. At the lowest powers, the voltage responsivity exceeds 10⁷ V/W. (b) shows variation of the dynamic photo-voltage responsivity (or, the contrast sensitivity dV_{OC}/dP) as a function of P in both devices A and B. In device B, the contrast sensitivity exceeds 10⁶ V/W at P≈10 nW, and the ˜P⁻¹ dependence is identical in both devices. The voltage response to (c) turning ON and (d) turning OFF of incident light in device B, showing exponential rise and fall behaviors with millisecond timescales. In all cases in this exemplary embodiment, the incident light wavelength was =488 nm.

FIGS. 7(a)-7(d) show the enhanced photoresponse by layer-thickening in one embodiment: (a) shows the (dark-current subtracted) photocurrent (in device A) as a function of incident power for different applied voltages, showing strong voltage dependence at higher powers. The inset shows the photoresponse of both devices A and B. A device-independent responsivity of 225 mA/W was obtained at V=−2 V that remains constant over the entire range of powers we were able to test (six orders of magnitude). (b) shows IPCE map of device A, demonstrating the high photon-to-electron conversion efficiency of ˜57% that may be tuned to remain constant over a large range of incident powers under reverse-bias operation. (c) shows variation of IPCE as a function of the incident power at representative operational voltages in device A. The dashed lines are guides to the eye. The IPCE remains nearly unchanged at V=−2 V, and goes →0 at V=0.2 V. This small voltage range (−2 V-0.2 V) may be used as a switch to turn the photocurrent on and off with a high switching ratio (>10⁴, see text). (d) shows transient photocurrent response in device B, showing that the devices were capable of switching within a few milliseconds. In all cases in this exemplary embodiment, the incident light wavelength was =488 nm.

FIG. 8 shows the spectral dependence of the noise-equivalent-power (NEP) and specific detectivity (D*) of device B in the photocurrent mode in one embodiment. The minimum NEP and the maximum D* were found to be 33 pW/Hz^{1/2} and 2.1×10⁸ Jones respectively, at λ=730 nm.

FIGS. 9(a)-9(c) illustrate the effect of doping in one embodiment: (a) shows variation of drain-current as a function of gate voltage in a monolayer graphene 3-terminal transistor without and with PCA doping. The shift of the minima towards higher gate voltages is indicative of p-type doping due to PCA. (b) shows the spectral dependence of IPCE (200 nm<λ<1100 nm) of device A (1 LG/Si) vs. a 3 LG/Si device before and after doping with PCA. (c) shows the spectral responsivity for the same devices within the same wavelength window. The improved bandwidth and efficiency/response in this embodiment is visible with increased layer thickness and doping. The doped 3 LG/Si device has the best IPCE exceeding 60% over a broad range, and with a maximum IPCE exceeding 65%. The responsivity peaks at ≈435 mA/W for 850 nm<λ<900 nm.

FIGS. 10(a)-10(b) shows SEM images of graphene in one embodiment: SEM images of graphene grown on (a) copper foils and (b) palladium foils. The inset shows higher magnification images from representative areas of the corresponding samples.

FIG. 11 shows, in one embodiment, Raman spectrum of a typical monolayer sample showing the typical characteristic of G and G′ peaks.

FIG. 12 shows an optical image of a 1 LG/Si device in one embodiment.

FIG. 13 illustrates the responsivity as a function of wavelength of the commercial Si-based photometer used to calibrate power in the experiments (provided by vendor) described in one embodiment.

FIG. 14(a) illustrates the Spectral dependence of the IPCE and the ACQE in a layer with TTG/Si sample with T(λ˜550 nm)˜30% in one embodiment. FIG. 10(b) shows variation of the mean IPCE and ACQE (averaged between 400-900 nms) as a function of layer thickness in one embodiment. Devices with the thickest layers have ACQE exceeding 90% over this broad range of photovoltaics-friendly wavelengths.

FIGS. 15(a)-15(b) show channel current as a function of gate voltage in pristine and doped graphene FETs in one embodiment: (a) pristine, (b) PCA doped, and (c) PCA+AuCl3. The shifting of the charge-neutrality point (V_{G}^{min}) to higher positive values indicates increased p-type doping of graphene.

FIG. 16 shows variation of IPCE and responsivity in the PCA-doped TTGc/Si device in one embodiment.

### DETAILED DESCRIPTION

Following are more detailed descriptions of various concepts related to, and embodiments of, an inventive system comprising tunable heterojunction and the methods of using and making same. It should be appreciated that various concepts introduced above and discussed in greater detail below may be implemented in any of numerous ways, as the disclosed concepts are not limited to any particular manner of implementation. Examples of specific implementations and applications are provided primarily for illustrative purposes.

### Graphene-Based Photodetectors

Graphene is a single-atom-thick, perfectly two-dimensional allotrope of carbon with exceptionally high carrier mobility, and broad-band optical absorbance and dynamic conductivity heralds a new paradigm for 2D photonics and optoelectronics. Graphene is both electrically conductive and optically transparent (a single layer of graphene absorbs only about 2.3% of light), and has been investigated for a variety of optoelectronic and photovoltaic applications. In particular, in the past few years, graphene-based photon-sensing and photo-switching devices have attracted enormous attention. The ultrafast dynamics in graphene potentially allow them to operate at >500 GHz switching frequencies, making them appealing for high-speed optical communications, whereas their broadband response makes them highly attractive as photodetectors that operate over a large span of wavelengths in the visible to NIR domain. In addition, the possibility of using low-cost, scalable, large-area, high-quality chemical vapor-deposition (CVD)-grown graphene makes them potentially attractive for scalable device-fabrication).

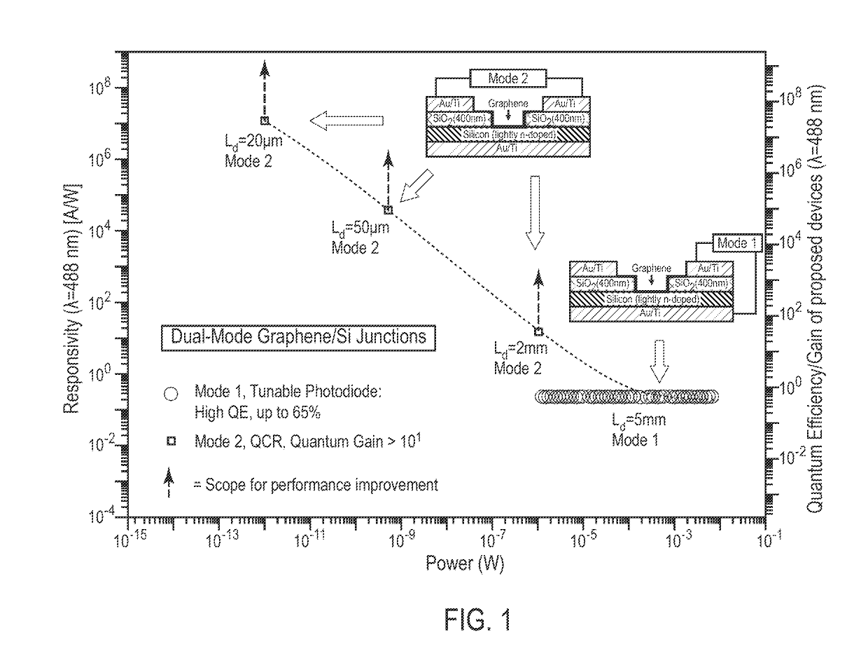

In the absence of any gain mechanism, an important limitation of photodetectors that use graphene as the photoabsorber is their low photocurrent (Iₚₕ) responsivity R(λ)=Iₚₕ/P, primarily due to the intrinsically low optical absorption (≈2.3%) of graphene. Within the visible to telecommunications-friendly wavelength range (i.e., 400 nm≦λ≦1550 nm), using both photovoltaic and photo-thermoelectric or hot-carrier effects along with enhancement techniques including asymmetric metal-contacts, plasmonic architectures, and micro-cavity confinements, R(λ) obtained has at best remained limited within 1−2×10⁻²A/W (see FIG. 1(a)). In addition, most of the above-mentioned devices used mechanically exfoliated graphene, and possess high carrier mobility, but are unsuitable for large-scale deployment. For realistic applications, high-performance devices using large-area chemical vapor deposition (CVD)-grown graphene without complex enhancement architectures are highly desirable. However, so far, a simple approach for obtaining high QE/responsivity graphene-based devices with high operational dynamic ranges, using simple, scalable and potentially low-cost techniques remains undemonstrated.

A recent device uses a hybrid structure of small pieces of mechanically exfoliated graphene from graphite and semiconductor quantum dots to obtain responsivity values >10⁷ A/W at incident powers well below P=10⁻¹³ W. The graphene/Si junctions, particularly those operated in Mode2 (as described below) in one embodiment have better performances (for devices of comparable size, comparable incident powers, and operated at less than half the voltage), as compared to this recent device. Further, the devices, particularly those operating in the modes as described herein, have the potential to improve by another two orders of magnitude in comparison to pre-existing devices. Moreover, in contrast to mechanically exfoliated graphene, which is unsuitable for large-scale deployment, by using large-area CVD-grown graphene overlaid on Si, the architectures described herein may remain conformal to conventional semiconductor processing, and will be able to span over ten decades or more of incident power using the combination of Mode1 and Mode2, as shown in FIG. 1.

### Mode 1

Provided in one embodiment is one operation mode, herein described as Mode1. Mode1 refers to a tunable photodiode mode, with high-responsivities (up to 435 mA/W) that may be obtained by reverse-biasing the device, layer thickening, and doping of graphene. In one embodiment, with low dark-current, linear photo-responses tested over at least four decades of incident power (P), quantum efficiency (QE)>65%, photoswitching ON/OFF ratios exceeding 10⁴ and photo-voltage responsivities exceeding 10⁴ V/W, the devices are highly suitable for tunable photoswitches, broadband (400 nm<λ<900 nm) photodetectors, photometers and imaging devices, and are also compatible with 850 nm optical interconnect technology.

In one embodiment Mode1 may include a method for operating a photodiode device comprising: providing a photodiode device, which device comprises: at least one layer of an n-doped semiconductor material; two portions of a dielectric material separately disposed over separate regions of the at least one layer of the n-doped semiconductor material; at least one monolayer of a carbon-based material disposed between the two portions of dielectric material and over the at least one layer of the n-doped semiconductor material; two terminal electrodes, each electrode disposed in electrical communication with a respective one of the portions of dielectric material; and a gate electrode in electrical communication with the at least one layer of the n-doped semiconductor material; applying a voltage across the gate electrode and one of the two terminal electrodes; and exposing the photodiode device to electromagnetic radiation. A measure of an electrical property of the photodiode device may provide a measure of the electromagnetic radiation incident on the photodiode device.

The method may further comprise growing the carbon-based material using a suitable technique. The technique may be, for example, deposition, including vapor deposition. Vapor deposition may include at least one of chemical vapor deposition and physical vapor deposition. In one embodiment, the method may further comprise disposing the carbon-based material over the at least one layer of the n-doped semiconductor material by transferring the carbon-based material onto a portion of a surface of the at least one layer of the n-doped semiconductor material. In one embodiment, the method may further comprise disposing the carbon-based material over the at least one layer of the n-doped semiconductor material by transfer printing a monolayer of the carbon-based material onto a portion of a surface of the at least one layer of the n-doped semiconductor material.

The n-doped semiconductor material may comprise any suitable semiconductor material. For example, the material may comprise silicon. The carbon-based material may comprise any suitable carbon-containing material. For example, the carbon-based material may comprise graphene. The carbon-based material may be doped, such as p-doped or n-doped. In one embodiment, the carbon-based material may be p-doped. The carbon-based material may be doped using any suitable dopant. In one embodiment, the dopant may be at least one of 1-pyrenecarboxylic acid and AuCl₃.

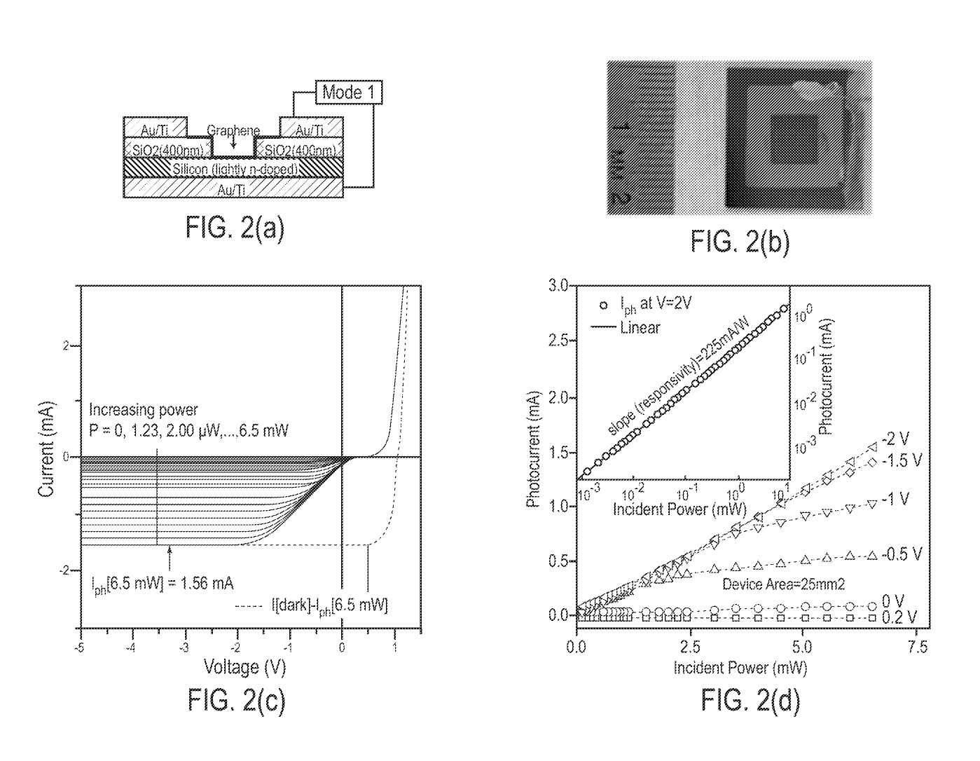

With respect to Mode1 (Tunable Graphene/Si Photodiode), graphene/Si junctions have been reported to form a Schottky-type barrier at the interface, and when illuminated, the photoexcitation of carriers occur in Si, resulting in carrier injection into graphene. These junctions were fabricated by a simple CVD method of graphene synthesis on Cu substrates, and their subsequent direct transfer on (lightly n-doped, n˜10¹⁵/cm³) Si windows. FIGS. 2(a) and 2(b) show a schematic and a digital photograph of a monolayer graphene (1 LG)/Si device, respectively. FIG. 2(c) shows the dark and photo-induced current-voltage characteristics of the device in the photodiode mode. (P=1.23 μW-6.5 mW, λ=488 nm) current-voltage (IV) curves. It is seen that at zero voltage, the current is low, whereas under an applied reverse-bias the current increases rapidly. The voltage-induced tunability of the (dark-current subtracted) photocurrent is hence voltage dependent, making it a tunable-response photodetector, as seen in FIG. 2(d). A high responsivity (˜225 mA/W, see inset of FIG. 2(d)), along with the low dark-current density (<<1 μA/cm²), results in a tunable photocurrent ON/OFF ratio exceeding 10⁴ at V=−2V and at a light intensity of 260 pW/μm² making them highly suitable for low-power switches in micron-scale optoelectronic circuitry. An absolutely linear response may be obtained over nearly four decades of incident power (FIG. 2(d) inset). The photocurrent responsivity of ˜225 mA/W, makes it an extremely sensitive photo-detector and photometer, with a large dynamic range. The linear response may potentially extend much beyond the experimentally tested range.

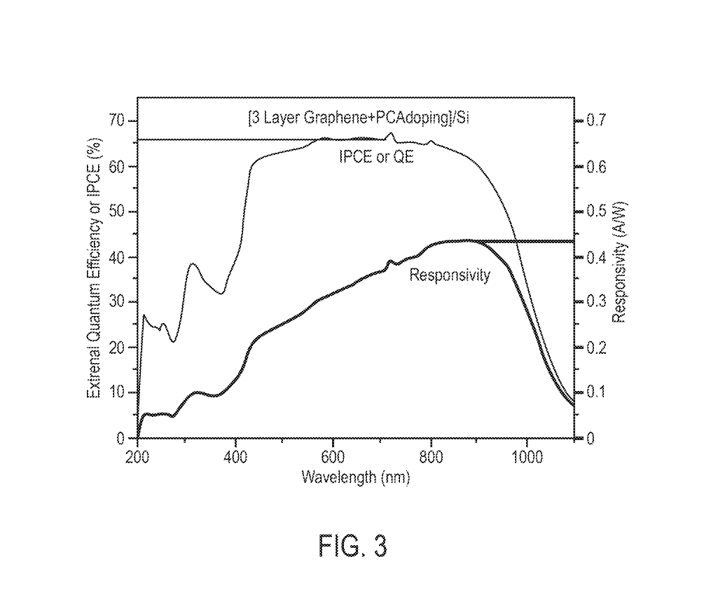

The conversion efficiencies may be further improved by increasing the layer-thickness of the carbon-based semiconductor layer (e.g., graphene layer), and p-type doping. Layer-thickening was achieved by multiple stacking of monolayer sheets graphene, while p-doping (FIG. 3(a)) was obtained using 1-pyrenecarboxylic acid (PCA). FIG. 3 shows the QE and responsivity of a 3 layer graphene (3 LG)/Si device after PCA doping. The QE and responsivity values reach a maximum QE>65% between 550 nm-800 nm; and R(λ)≈435 mA/W for 850 nm<λ<900 nm, making it highly compatible with the high-performance, energy efficient, 850 nm optical interconnect technology.

Operating in Mode1, which is a tunable photodiode mode, high-responsivities (up to 435 mA/W) may be obtained by voltage-tuning the Fermi levels, layer thickening, and doping of graphene. With low dark-current, linear photo-responses tested over at least four decades of incident power (P), quantum efficiency (QE)>65%, ON/OFF ratios exceeding 10⁴ and photo-voltage responsivities exceeding 10⁴ V/W, these devices are highly suitable for tunable photoswitches, broadband (400 nm<λ<900 nm) photodetectors, photometers and imaging devices, and are also compatible with 850 nm optical interconnect technology.

### Mode2

Provided in one embodiment is an operation mode, herein described as Mode2. Mode2 uses a proposed new mechanism, the Quantum Carrier Reinvestment (QCR) method, whereby ultra-high quantum gain exceeding 10⁷ has already been achieved at low incident powers, corresponding to a responsivity≈10⁷A/W at λ=488 nm. The responsivity values depend on device size (see FIG. 1(a)), and operational voltages (tested at low V so far), and are expected to improve further with improved graphene quality and at higher wavelengths, overall by at least another two orders of magnitude. In this mode, ultra-low incidence high-contrast on-chip imaging, and possible on-chip single-photon detection is envisioned. It is possible to include techniques for color-selective and polarization-selective sensing. The components of the device and the steps involved in the method may be any of those described above.

In one embodiment, Mode2 may include a method for operating a photodiode device comprising: providing a photodiode device, which device comprises: at least one layer of an n-doped semiconductor material; two portions of a dielectric material separately disposed over two separate regions of the at least one layer of the n-doped semiconductor material; a carbon-based material disposed between the two portions of the dielectric material and over the at least one layer of the n-doped semiconductor material; two terminal electrodes, each electrode disposed in electrical communication with a respective one of the two portions of dielectric material; and a gate electrode in electrical communication with the at least one layer of the n-doped semiconductor material; applying a voltage across the two terminal electrodes; and exposing the photodiode device to electromagnetic radiation. A measure of an electrical property of the photodiode device may provide a measure of the electromagnetic radiation incident on the photodiode device.

With respect to Mode2 (the Quantum Carrier Reinvestment Mode), since photo-excited holes may inject into graphene, these may effectively “dope” graphene (photogating effect), resulting in a change in its sheet resistance. Under an external voltage V across the graphene sheet (applied using electrical leads at its two ends) this will result in a change in sheet current when photons are incident, arising from the “borrowed” holes from silicon. As each borrowed hole moves out through one electrode, it is replaced by another one from the opposite end, and these holes are effectively replaced multiple times within graphene until it recombines with an available electron in silicon. During this timescale, determined by the quantum-mechanical probability of recombination (lifetime), the borrowed carrier may be “reinvested” several times into the external circuit, adding to the net “photocurrent,” and leading to a quantum gain.

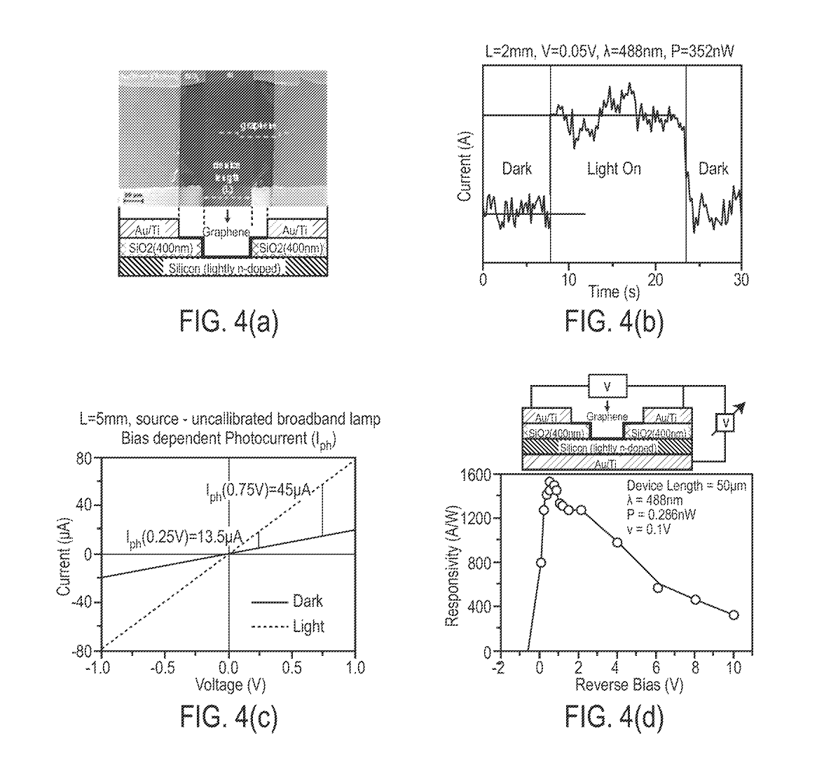

If the drift velocity of the holes (in an analogy to free electron theory) may be written as v_{d}=(1/mₕ)×|e|Eτ, where mₕ is the effective mass of holes in graphene, E is the applied electric field (=V/L), L=active device length, and τ is the internal relaxation time in graphene, then the Quantum Gain may be expected to be proportional to a ratio of v_{d} and the recombination rate (τᵣ⁻¹) of the extra holes back into silicon, i.e. QG∝v_{d}/τᵣ⁻¹. Not to be bound by any theory, but this implies that the Quantum gain (and Responsivity) should be directly proportional to the applied voltage (V) (as seen in FIG. 4(c)) and inversely related to the device length (L) (as seen in FIG. 1). Further, since a simultaneous application of a reverse bias (hybrid mode) may potentially “draw away” the extra electrons in silicon from the junction, effectively reducing the recombination rate τᵣ⁻¹, this may also enhance the Responsivity (as seen in FIG. 4(d)).

An L˜20 micron device (operating at 2V) possessed the (so far) highest obtained responsivity of ˜10⁷A/W (QG≈2.5×10⁷), implying a spectacular >10⁷ electrons detected per 1 photon. In one embodiment, by lithographically reducing the device size to micron scales, applying higher channel voltages and appropriate reverse biases, and improving the quality of graphene, the responsivity (and quantum gain) of these devices may be increased by at least another two orders of magnitude.

Mode2 may employ a mechanism, the Quantum Carrier Reinvestment (QCR) method whereby ultra-high quantum gain exceeding 10⁷ has already been achieved (corresponding to a responsivity≈10⁷A/W at λ=488 nm). The responsivity values depend on device size (see FIG. 1(a)), operational voltages (tested at low V so far), and are expected to improve with graphene quality and at higher wavelengths. One embodiment of the systems and methods described herein may enhance the responses by at least another two orders of magnitude. In one embodiment, in this mode, paradigm-changing, ultra-low incidence, and possible on-chip single-photon detection may be achieved.

### Hybrid Mode

At least one certain aspect of Mode1 and Mode2 may be employed in combination as a hybrid mode. The components of the device and the steps involved in the method may be any of those described above.

Provided in another embodiment is a method for operating a photodiode device comprising: providing a photodiode device, which device comprises: at least one layer of an n-doped semiconductor material; two portions of a dielectric material separately disposed over separate regions of the at least one layer of the n-doped semiconductor material; a carbon-based semiconducting material disposed between the two portions of dielectric material and over the at least one layer of the n-doped semiconductor material; two terminal electrodes, each electrode disposed in electrical communication with a respective one of the portions of dielectric material; and a gate electrode in electrical communication with the at least one layer of the n-doped semiconductor material; applying a voltage across the gate electrode and one of the two terminal electrodes; exposing the photodiode device to electromagnetic radiation; measuring an electrical property of the photodiode device to provide a measure of the electromagnetic radiation incident on the photodiode device; and applying the voltage across the two terminal electrodes if the measure of the electromagnetic radiation incident on the photodiode device falls below a predetermined threshold value.

In one embodiment, the method may further comprise providing a second photodiode with an active region of reduced lateral dimensions when the measure of the electromagnetic radiation incident on the photodiode device falls below a predetermined threshold value; and exposing the second photodiode to the electromagnetic radiation. A measure of an electrical property of the second photodiode device may provide a measure of the electromagnetic radiation incident on the second photodiode device.

### Applications

By reducing the device length by an order of magnitude, performing measurements at higher biases (10 V or higher), improving the graphene mobility by up to another order of magnitude, operating in a slightly reverse-bias mode (hybrid mode, see FIG. 4(d)) and by locating the wavelength corresponding to highest responsivity (FIG. 3), devices with responsivities of at least ˜10⁹A/W may be obtained.

The systems and the operation modes described above may be employed in and applied to any suitable applications. Exemplary applications may include tunable, large dynamic range, ultra-sensitive photodetectors, single photon counters, ultra-linear photometers, photoswitches, and the like. In one embodiment with metamaterial/plasmonic enhancement, the systems and devices described herein may be employed for color/polarization sensing. In another embodiment, the systems and devices described herein may be mounted on microscopes with X-Y stages in the application of on-chip atto-chemistry. In another embodiment with increased layer thickness and doping, the systems and devices described herein may be employed in low-cost photovoltaics. In another embodiment, with silicon replaced by other semiconductors, the systems and devices described herein may be employed in infrared detectors and sensors, imaging devices. In another embodiment, the systems and devices described herein may be employed in on-chip optical interconnects.

The systems and the operation modes described above may be employed towards Single-Photon detection. At this point, the best responsivity obtained is about 10⁷ A/W in an L˜20 μm device, measured at 2 V and at λ=488 nm. By reducing the device length by an order of magnitude, performing measurements at higher biases (10 V or higher), improving the graphene mobility by up to another order of magnitude, operating in a slightly reverse-bias mode (hybrid mode) and by locating the wavelength corresponding to highest responsivity, the systems and the operating modes described may be employed to obtain devices whose responsivities may be potentially increased to at least about 10⁹A/W, entering a regime of unprecedented sensitivity for a bare, on-chip heterojunction detector.

In another embodiment, preliminary data show that a Iₚₕ˜50 nA=Iₚₕ(min) may be reasonably detected over the noise level (even without a lock-in amplifier). This implies that a successful improvement of the device performance may increase its responsivity up to R˜10⁹ A/W, and the lowest detectable power, P(min)=Iₚₕ(min)/R≈will be about 50×10⁻¹⁸ W. At λ=500 nm, this corresponds to about 125 photons per second. Hence measurements are performed at 1 kHz will potentially detect single photon events! In order to test these limits, a specially designed dark vacuum chamber with appropriate grounding and shielding along with a small optical window and with electrical feed-through is being designed. The atto Watt incidences needed for single-photon detection may be obtained by using well-calibrated laser sources, an array of low-transmittance filters with calibrated transmittances, and appropriate beam-expanders.

### NON-LIMITING WORKING EXAMPLES

### Example 1

This example provides the photodetection properties of graphene/Si heterojunctions both in the photocurrent and photovoltage modes in one embodiment. Monolayer graphene/Si junctions were found to be excellent weak-signal detectors with photovoltage responsivity exceeding 10⁷ V/W with noise- equivalent-power reaching ˜1 pW/Hz^{1/2}, potentially capable of distinguishing materials with transmittance, T=0.9995 in a 0.5 second integration time. In the photocurrent mode, the response was found to remain linear over at least six decades of incident power (P), with tunable responsivity up to 435 mA/W (corresponding to incident photon conversion efficiency (IPCE) >65%) obtained by layer thickening and doping. With millisecond-scale responses and ON/OFF ratios exceeding 10⁴, these photodiodes are highly suitable for tunable and scalable broadband (400<λ<900 nm) photodetectors, photometers, and millisecond-response switching, spectroscopic and imaging devices, and further, are architecturally compatible with on-chip low-power optoelectronics.

Nanoscale materials, due to their diverse electronic and optical properties, and with a range of architectures, are explored for an array of low-cost, sensitive and scalable photodetection technologies. For example, nanowires of conventional pre-existing semiconductor materials (e.g., Si, Ge, GaN, GaAs, InP, etc.) may provide a versatile platform for photodetection, affording direct structural and functional compatibility with existing photonic and optoelectronic circuitry. In contrast, low-cost solution-processable quantum dots may be appealing due to their potentials for large-area and flexible-electronic applications. Their photoconductive response characterizes high quantum gains resulting in ultra-high responses (˜10³ A/W) and specific detectivities (˜10¹³ Jones). Nanoscale junctions of quantum dots with metals have also been reported to have ultra-fast responses of the order of GHz. Similarly, carbon nanotubes, with their extremely narrow diameters and chirality-dependent band-gaps may be potentially utilized for spectrally selective photodetectors of ultra-small dimensions.

In this context, graphene-based photon-sensing and photo-switching devices have recently attracted attention for their ultrafast and broadband response. Although these devices are highly appealing for ultrafast optical communications, they may suffer limitations including weak signal detection, imaging, and spectroscopic applications due to their low responsivity values. Within the visible to telecommunications-friendly wavelength range (i.e. 400 nm≦λ≦1550 nm), using both photovoltaic and photo-thermoelectric or hot-carrier effects along with enhancement techniques including asymmetric metal-contacts, plasmonic architectures, and micro-cavity confinements the photocurrent responsivity (R_{I}=Iₚₕ/P) has at best remained limited within 1−2×10⁻²A/W. These low responses have been primarily attributed to the intrinsically low optical absorption (≈2.3%) of graphene along with the absence of any gain mechanisms.

By using graphene as the carrier collector and multiplier, an effective gain mechanism (with R_{I}>10⁷A/W) was recently reported in graphene/quantum-dot hybrid devices. Despite their appeal for ultra-weak signal detection, the responsivity of these devices above P≈10⁻¹³ W fall as R_{I}˜1/P, implying a rapid photocurrent saturation above these incident light powers. With considerably large dark currents that render them ineffective as photoswitches (ON/OFF ratio <<1) and large dark-power consumption, they are impractical for many large-scale applications (such as pixels in imaging devices that need large arrays of photodetectors).

For many applications, photovoltage (instead of photocurrent) measurements are preferred as a sensitive method for photodetection without any Joule-heating associated power consumption. Past works reveal that metal-graphene interfaces may generate photovoltages of ˜1 V/W,⁵ which may be enhanced to ˜5 V/W using plasmonic focusing and appropriate gate voltages. It appears the limits of photovoltage response for low dark-current graphene-based devices, especially under weak signals (where the high responsivities are more meaningful), has not been investigated in detail. Further, most of the above-mentioned devices used mechanically exfoliated graphene, which possess high carrier mobility, but is unsuitable for large-scale deployment. For realistic applications, high-performance devices using large-area chemical vapor deposition (CVD)-grown graphene without complex enhancement architectures are highly desirable. However, so far, a simple approach for obtaining tunable high-responsivity graphene-based devices with low dark currents, low-power detection limits and high operational dynamic ranges, using simple, scalable and potentially low-cost techniques remains undemonstrated.

This Example shows that in one embodiment planar 2D heterojunctions of CVD-grown graphene and Si in a conventional Schottky-diode-like configuration may effectively address these issues, providing a platform for a variety of optoelectronic devices. In these junctions, the photoexcitation resides in Si while graphene is the carrier collector. A number of works have explored the unique properties of graphene/Si heterojunctions to develop diodes, solar cells, and the so-called “barristor”—a variable-barrier switch. However, so far, these junctions have not been examined for ultra-sensitive photodetection for applications (e.g., weak-signal imaging or spectroscopy). Further, in these junctions, low reverse-biases may effectively manipulate the Fermi-levels of graphene (unlike larger voltages that are needed in capacitively coupled gates). The ability to tune the dark Fermi level (E_{f}(Gr)) of graphene, and more importantly, its relative position with respect to the quasi-Fermi level for holes in silicon (E′_{f,h}(Si), the modified Fermi level due to the generation of photo-excited holes in Si) is an important mechanism that may enable a high degree of tunability and efficient capture of photoexcited carriers, resulting in high photocurrent responsivity values whose performances may be dramatically improved by layer-thickening and simple doping approaches. The tunable photocurrent responsivity is an attractive feature for adjustment to variable-brightness imaging applications. At the same time, these junctions also possess exceptionally high photovoltage response, which increases with decreasing incident power, making it highly suitable as weak-signal detectors in the photovoltage mode. In this Example, the various important parameters of such applications were investigated—e.g., responsivity, detection limit, switching speed, ON/OFF ratio, spectral bandwidth, contrast sensitivity, and dynamic range in monolayer and few-layered graphene/Si heterojunctions, operating both in photocurrent and photovoltage modes.

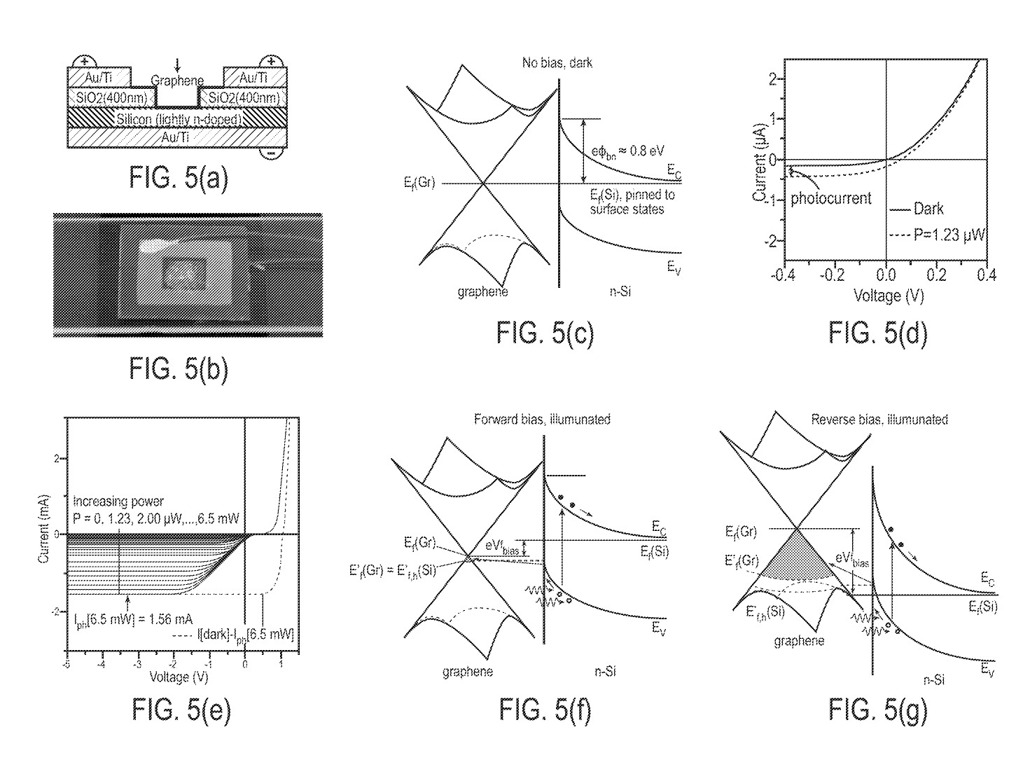

The photoresponse behaviors were first tested in monolayer graphene (1 LG)/Si devices and their intrinsic parameters were found to be mostly independent of size. The results obtained include those from the largest (device A) and the smallest (device B) devices with junction areas =25 mm² and 5000 μm², respectively. Lightly n-doped Si (ρ=1−10 Ωcm) was employed, and the details of device fabrication and characterization may be found in Example 2. FIG. 5(a) shows a schematic of a typical monolayer graphene (1 LG)/Si device, and FIG. 5(b) shows a digital photograph of device A. The energy band diagram, showing the Fermi levels of graphene (E_{f}(Gr)) and lightly n-doped Si (E_{f}(Si)) at thermal equilibrium (in a dark condition) is shown schematically in FIG. 5(c). From detailed measurements of the Schottky barrier heights (as discussed later on), it was found that in the devices in this Example, E_{f}(Si) was pinned to the charge-neutrality level of its own surface states, with a Schottky barrier height φ_{bn}˜0.8 V. FIG. 5(d) shows the dark and low-power (P=1.23 μW, λ=488 nm) current-voltage (IV) curves in device A, which follow a conventional rectifying and photodiode-like behavior, respectively.

Incident photons generate e-h pairs in Si, and these photoexcited carriers thermalize rapidly to form quasi Fermi levels (separately for holes and electrons near the valence and conduction band edges (VBE and CBE) of Si, respectively). Not to be bound by any theory, but the built-in electric field at the graphene/Si junction causes holes to inject out from Si (from the small energy-band between the VBE and quasi Fermi level for holes in Si) into graphene, which causes the appearance of a quasi Fermi level in graphene, E′_{f}(Gr). The position of the quasi Fermi level in graphene depends on (a) the position its bias-dependent E_{f}(Gr) and (b) the number of injected holes from Si. At low incident powers, E′_{f}(Gr) lies between E_{f}(Gr) and E′_{f,h}(Si), and the photo-excited holes may all find accessible states in graphene to inject into, resulting in the conventional photodiode-like response.

FIG. 5(e) shows the IV curves under increasing incident light powers (up to P=6.5 mW). At higher incident powers, there is a significant deviation of the IV curves from the conventional photodiode-like response, with a strong suppression of photocurrents close to V=0, and a sharp rise and rapid saturation of photocurrents at low reverse biases. This highly tunable photocurrent response is a result of the unique electronic structure of graphene near its Fermi level.

FIG. 5(f) schematically represents the situation under a low forward bias, V^{f}_{bias}, which lowers the Fermi level from its “unbiased” position. As seen in this figure, the lowering of the Fermi level brings it closer to the quasi Fermi level for holes in Si, greatly diminishing the number of accessible states for the photo-excited carriers to inject into from Si. Hence, under a forward bias, with increasing incident power and rate of hole-injection, E′_{f}(Gr) lowers and quickly aligns with E′_{f,h}(Si) (E′_{f}(Gr)=E′_{f,h}(Si), FIG. 5(f)). Consequently, only a relatively small photocurrent (denoted by the small red part of the surface of the Dirac cone), limited by the small number of photo-excited holes that may inject into graphene, is possible under forward bias. Increasing the incident light power beyond this point will not allow any more photoexcited holes to inject into graphene since E′_{f}(Gr) cannot lie below E′_{f,h}(Si). However, an applied reverse-bias may lift E_{f}(Gr) to higher values, as shown in FIG. 5(g), opening up a large number of accessible states for the holes to inject into, and allowing a complete collection of the injected holes. As a result, the photocurrent, which is significantly suppressed near V≈0, may completely recover under small reverse biases, as seen in FIG. 5(e). (These deviations from a conventional photodiode behavior are explained with additional schematics in Example 2).

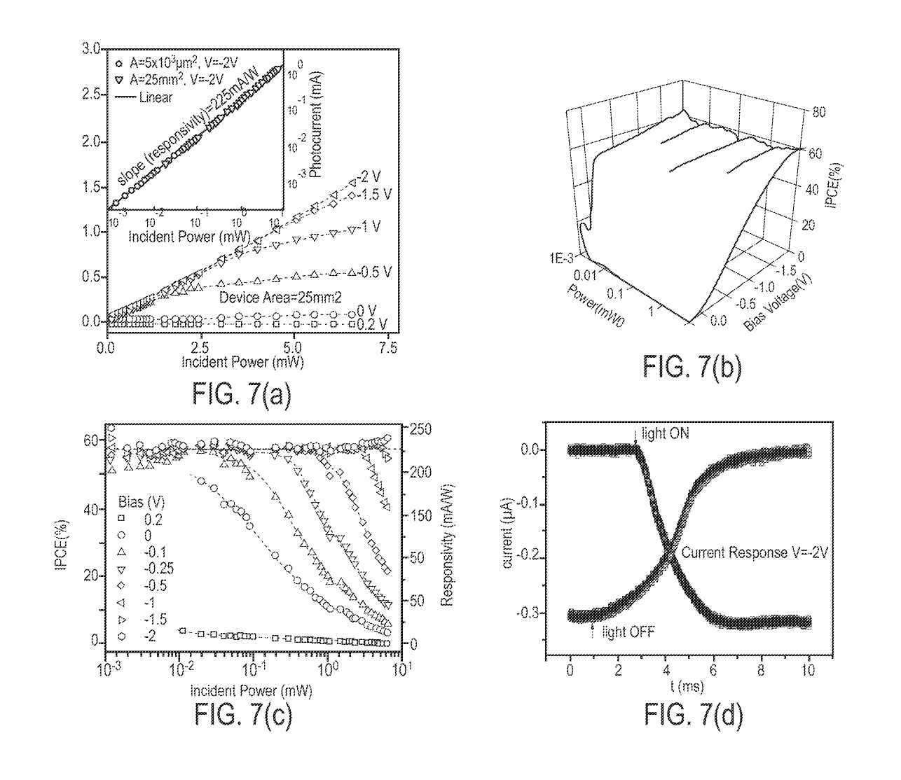

The photocurrent saturates for a given incident power at higher reverse biases (FIG. 5(e)) when all photoexcited holes may inject into graphene. The photocurrent saturates for a given bias at higher incident powers (see FIG. 7(a)) when the quasi-Fermi level in graphene, E′_{f} (Gr) reaches the quasi-Fermi level for holes in Si, E′_{f,h} (Si). The voltage-induced tunability of the relative positions of the Fermi levels that enables a high photocurrent responsivity (as shown later), along with the low dark-current density (<<1 μA/cm²), results in a tunable photocurrent ON/OFF ratio exceeding 10⁴ at V=−2V and at a light intensity of 260 pW/μm² making them highly suitable for low-power switches in micron-scale optoelectronic circuitry.

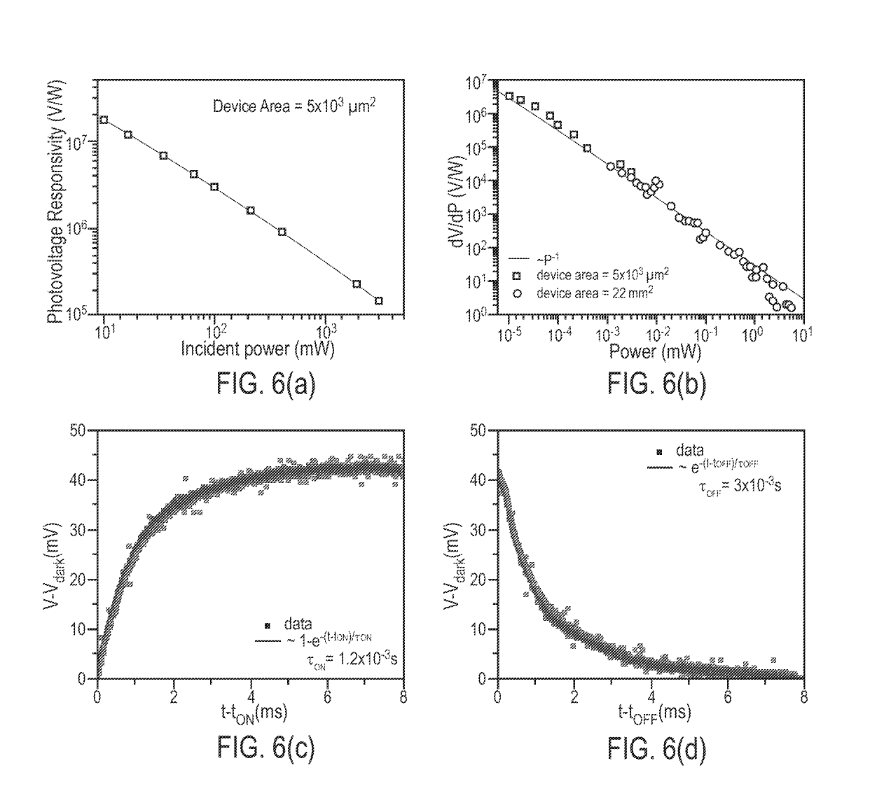

FIG. 6(a) shows the photovoltage responsivity in device B as a function of incident power. At the lowest incident power, the absolute device responsivity R_{V}(=V_{OC}/P, V_{OC} is the open circuit voltage) exceeds 10⁷ V/W, which is significantly larger than that of previously reported graphene-based devices, rendering it a highly sensitive device for weak signal detection/switching/photometry. For applications including weak-signal imaging, video-recording or analytical chemistry, sensitivity to small changes in incident power is another important parameter.

To quantify this, in this Example the dynamic photovoltage responsivity or contrast sensitivity is defined as dV_{OC}/dP. FIG. 6(b) shows the contrast sensitivity in both devices A and B, measured over a broad range of incident powers. It was observed that the contrast sensitivity is relatively independent of the device areas, exceeding 10⁶ V/W at low light intensities. In addition, these devices show a sharp rise in both the absolute and dynamic responsivity as the incident power decreases, which is a convenient feature appropriate for weak-signal detection.

For a photodetector, the detection limit may be specified by the noise-equivalent-power (NEP), which is the incident power at which the signal is equal to the RMS dark noise density (S_{V}), measured within a specified bandwidth (commonly 1 Hz), i.e. NEP=S_{V}/R_{V}. To obtain S_{V}, a large sequence of voltage fluctuations (Vₙₒᵢₛₑ) was measured using a voltmeter set to 0.5 seconds integration time (which corresponds to a bandwidth of 1 Hz), while keeping the device in darkness. The RMS noise density was then calculated as s_{V}=\sqrt{V(<V²ₙₒᵢₛₑ>)/1 Hz}. For the device B, it was obtained S_{V}=1.66×10⁻⁵ V/Hz^{1/2}. From the lowest measured power of 10 nW, R_{V}≈1.8×10⁷ V/W, and hence NEP=9.2×10⁻¹³ W/Hz^{1/2}. Not to be bound by any theory, but this implies that in the photovoltage mode, P˜pico Watt incidences may be detected above the noise level, when integrated over 0.5 seconds, and specific detectivity D*=\sqrt{device area}/NEP=7.69×10⁹ Jones (cmHz^{1/2}/W). Further, at 10 nW incidence, S_{V}/(dV_{OC}/dP)≈5 pW/Hz^{1/2}, indicating that these detectors are capable of distinguishing materials with transmittance, T=0.9995 (to compare, transmittance of monolayer graphene is about 0.977) within a 0.5 second integration time, making it useful for absorption spectroscopy applications of ultra-dilute or ultrathin materials.

The transient-response timescale of these detectors was also investigated to ascertain how quickly they “switch” when an incident light is turned “on” or “off”. To do this, an optical chopper was placed in front of a laser source and the photovoltage was recorded as a function of time using an oscilloscope triggered by the same chopper. FIGS. 6(c) and 6(d) show the photovoltage rise and fall response times obtained using a 50 millisecond timed optical chopper (which took about ˜1.7 milliseconds to completely chop the beam). In both cases, the response could be fitted to an exponential function as shown, with timescales of a few milliseconds (with the zero on the time axis corresponding to the point of opening and closing the chopper).

When tested at higher chopping speeds, no change was found in the time-scale of the transient response, indicating that the response-time of a few milliseconds was intrinsic to the devices. It was noted that the oscilloscope used had an input-impedance rated at 1 MΩ in parallel with a 20 pF capacitance. The effective time constant of the oscilloscope, RC,=20×10⁻⁶ seconds, is ˜3 orders of magnitude smaller than the rise/fall time of the devices tested, and hence did not affect detector transient response in any significant way.

In addition, the long-term response to a periodically switching light was found to be extremely stable, with a variation of the OFF and ON state photovoltages well within ±2.5% and ±5%, respectively, over 1000 switching cycles, and with absolutely no sign of drift or ageing effects even after 10 days (see Example 2). The stable, millisecond level response is quite appealing for applications, such as high-speed photography, videography, and rapid optical analysis of chemical reactions that need tens of milliseconds of response time.

The photocurrent response was also investigated. FIG. 7(a) shows the photocurrent Iₚₕ as a function of incident powers for various biases in device A. In the inset, the response for V=−2V has been plotted for both devices. The response not only remains independent of device size, but scales in an absolutely linear manner over six decades of incident power. The photocurrent responsivity of ˜225 mA/W is 1-2 orders-of-magnitude higher than those of graphene-based photodetectors, and a variety of normal-incidence (i.e. not waveguide coupled) Ge/Si photodetectors, making it a sensitive linear photo-detector and photometer with a large dynamic range.

The responsivity may be almost doubled at λ=850 nm, as shown later. Also, the presented power range is only limited by the instrumental capabilities, and with higher reverse-biases, the linear response may potentially extend much beyond the experimentally tested range. The range-independent photocurrent responsivity and the dV_{OC}/dP˜1/P dependence suggests that the underlying mechanism in our devices is photovoltaic, and not hot-carrier-induced or photo-thermoelectric.

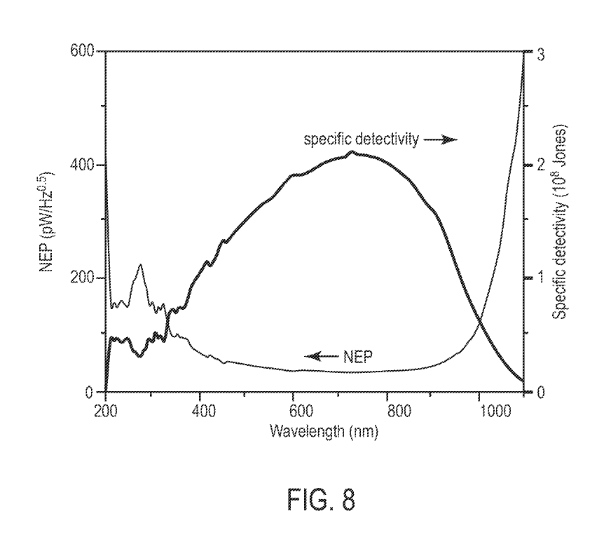

FIG. 7(b) is a 3D incident photon conversion efficiency (IPCE(V,P)=(Iₚₕ(V,P)/P)×(hc/eλ)) map of device A. By applying a low reverse bias, the device may operate with an IPCEₘₐₓ˜57% over four orders-of-magnitude incident power. As shown in FIG. 7(c), by applying different biases, it is also possible to almost completely tune the IPCE between 0<IPCE<IPCEₘₐₓ, which is useful for brightness adjustment in imaging devices. FIG. 7(d) shows the typical rise and fall times in response to a chopper in one embodiment. In this case, the responses could not be fitted to exponential functions. Nevertheless, it is clear that even in the case of photocurrent detection, the response is rapid enough (within a few milliseconds) for many imaging and analytical applications. The dark noise power spectral density, (obtained in a manner similar to the one described earlier for S_{V}), was approximately S_{I}=11 pA/Hz^{1/2}. For the un-doped 1 LG/Si device at 488 nm, this gave a NEP=S_{I}/R_{I}=50 pW/Hz^{1/2} which corresponds to a specific detectivity of 1.4×10⁸ Jones (cmHz^{1/2}/W), making it quite a sensitive photodetector even in the photocurrent mode. Moreover, the sensitive behavior of these detectors remains intact over the entire visible range of incident wavelengths, as seen from the spectral dependence of NEP and D* in FIG. 8, which is an important criterion for broadband imaging applications.

Not to be bound by any theory, but the photo-current responsivity and hence conversion efficiencies could be further improved by at least one of (i) increasing the graphene layer-thickness and (ii) doping. Layer-thickening provides more states for the holes to inject into, and was achieved by multiple stacking of monolayer sheets of graphene in this Example. Doping the graphene sheets may be expected to increase their sheet conductance, and has been utilized in the past to enhance the performance of graphene/Si Solar cells. In the devices presented in this Example, p-type doping of the graphene sheets was obtained by drop-casting 1-pyrenecarboxylic acid (PCA), on the graphene sheets. Not to be bound by any theory, but the π-stacking interaction between the pyrene part of PCA and graphene may lead to a stable but non-covalent attachment of these molecules to graphene. In particular, it was found that attachment of PCA does not seem to have a very significant effect on the thickness of graphene layers, but increases the surface roughness of graphene by about 0.2 nm (see Example 2).

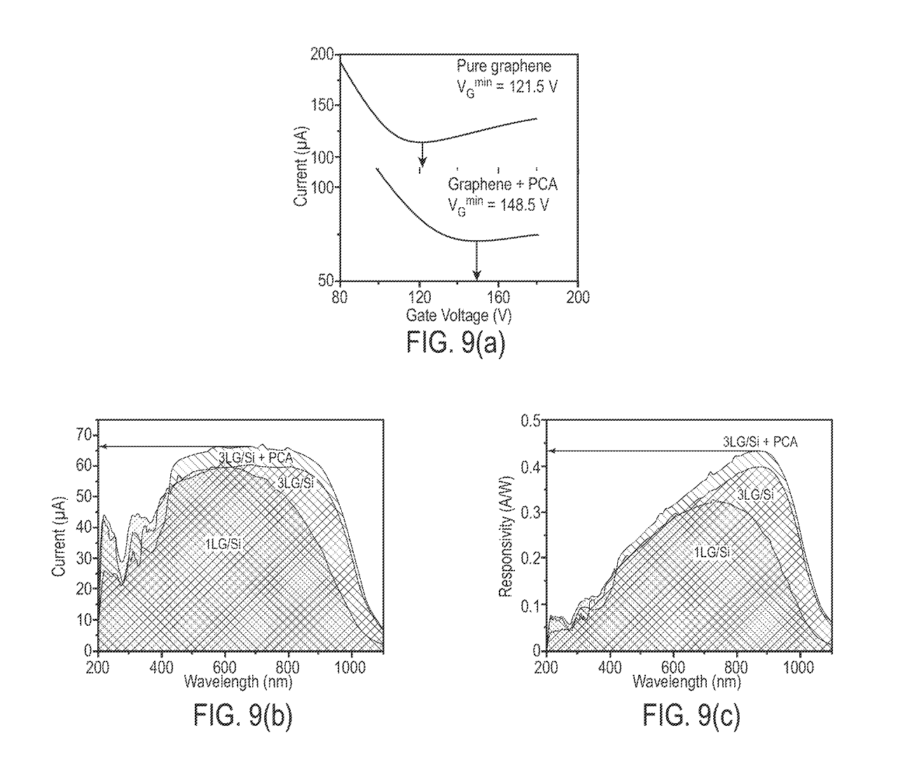

In addition, Raman spectra of PCA-doped graphene shows an increase in the D-band (see Example 2) that is likely due to the presence of large number of edges in the graphene-like crystalline structure of pyrene. FIG. 9(a) shows the resulting p-type doping effect of PCA on a separately prepared 3-terminal 1 LG transistor. The drain current minimum of pristine graphene devices is at a positive voltage, indicating that the “pristine” graphene is already p-doped, either due to environment or contaminant effects. In at least one case, application of PCA shifts the drain current minimum to higher gate voltage values, indicating an additional p-doping effect. FIGS. 9(b) and 9(c) compare the spectral dependence of IPCE and photocurrent responsivity in a three-layer graphene (3 LG)/Si device (with and without doping) vis-à-vis the 1 LG/Si device A, all of which had the same junction area. The IPCE of 3-layer graphene (3 LG)/Si device improves over that of the 1 LG/Si device, remaining at ˜60% over a larger window of visible wavelengths. The corresponding responsivity grows to higher values (up to ˜0.4 A/W at λ=885 nm) in the 3 LG/Si device, providing a greater operational bandwidth compared to the 1 LG/Si device. After PCA doping, the IPCE and responsivity values increase further over a large window of wavelengths, with maximum IPCE≈65% between 550 nm-800 nm; and R_{I}≈435 mA/W for 850 nm<λ<900 nm, making it appealing for on-chip applications that could benefit from the use of energy-efficient 850 nm VCSELs. It is noted that as in the case of the 1 LG/Si device, these improved responsivity/IPCE values could be seamlessly extended to high-power applications using low reverse biases (not shown).

Moreover, the nature of the interface in these junctions was investigated. Measurements of the Schottky barrier height of these junctions were performed, using graphene, doped graphene, and even control devices of Ti/Au with Si (in order to obtain the “metallic” side of the junction with a range of work-function values). Since p-doping may lower the Fermi level of graphene with respect to its Dirac point, it at least one embodiment one may expect a larger Schottky barrier height, for the p-doped graphene samples. Surprisingly, it was found that the Schottky barrier φ_{bn}=0.79±0.05 eV was nearly independent of the “metal” being used.

In one embodiment, in an ideal Si Schottky junction the interfaces between the metal and Si is expected to be atomically clean to prevent the formation of any surface states on Si, resulting in the formation of an “unpinned” Schottky barrier junction, whose barrier height φ_{bn} (=φₘ−χ_{Si}) is dependent on the work-function of the metal, φₘ. In thermal equilibrium, the Fermi levels on both sides of the junction may get aligned, and under illumination behaves as conventional photodiodes with a reverse-bias independent photocurrent. By contrast, not to be bound by any theory, but in the devices presented in at least this Example the inadvertent formation of natural oxide on the Si surface allows the energy bands in Si to naturally “pin” itself to its own surface states. This results in a Schottky barrier which is still rectifying but with a barrier-height which is pinned to its Bardeen limit of φ_{bn}˜0.8 eV, independent of the work function of the metal.

With the Fermi level of Si pinned to its own charge-neutrality level, the thermal equilibrium position of the Fermi level of graphene at zero bias is determined by its own intrinsic doping level. UV-emission spectroscopy has shown that CVD grown graphene may have work functions as high as 5.2 eV (due to substrate-induced effects), implying that the Fermi level may lie very close to the valence band edge of Si, effectively preventing the injection of photo-induced carriers into graphene under zero applied bias. Not to be bound by any theory, but this causes the suppressed photocurrent at zero-bias observed in at least some of the devices described herein. Surprisingly, this becomes an attractive feature, as it allows for an additional tunability of the photocurrent that results in the voltage-controllable responsivity discussed above.

In sum, graphene/Si heterojunctions may be used for a variety of tunable optoelectronic devices with high responsivities over a broad spectral bandwidth in the visible region. Their high responses and low dark-currents result in a high switching ratio and low dark-power consumption. The picoWatt-level detection capability in both photovoltage and photocurrent modes along with linear operation demonstrated up to milliWatts of incident powers reflects a significantly large dynamic operational range. This, in addition to their millisecond-responses makes them versatile and highly sensitive photodetectors for a variety of imaging, metrology, and analytical applications over a broad range of input powers. The voltage-tunability allows brightness control for variable light conditions and enables linear operation over a large dynamic range. The responsivity peaking at 850 nm is desirable for coupling with VCSELs operating at these wavelengths for low-power integrated optoelectronic circuitry. Built using simple, low-cost, and scalable methods, additional improvements of CVD-graphene quality, integration with as wave-guides, and plasmonic or micro-cavity enhancements could lead to greater performances. Moreover, graphene junctions with other semiconductors such as Ge, GaAs etc., may provide further flexibility for controlling the peak-responsivity, spectral bandwidth, and high-speed operations.

### Example 2

### S1. Synthesis of Graphene (1 LG) and Thin Transparent Graphite (TTG)

Large-area graphene (mostly monolayer, 1 LG, see section S2 below) was grown on commercially purchased Cu foils in a low-pressure chemical vapor deposition (CVD) system. The copper foils were annealed in a flow of 7 sccm H₂ for 30 min under 1015° C. to increase the grain size of copper and to clean the copper surface of any unwanted oxide or physisorbed species before growth. After that, CH₄ was introduced (flow-rate of 25 sccm) into the system to grow graphene for t=30 mins. The chamber was then cooled down to room temperature with flowing H₂ in the system.

Thin transparent graphite (TTG) samples were synthesized on Pd substrates, using a similar low pressure CVD method. It was observed that high-quality graphene may grow easily on Pd in a manner somewhat similar to those previously reported for Ni substrates, rapidly forming multilayer and thin graphitic region at high growth temperatures. The palladium foils were annealed in gas mixture of 7 sccm H₂ and 50 sccm Ar for 30 min to clean the Pd surface before growth. To obtain large-area very thin transparent graphite (sample TTGa and TTGc), a higher growth temperature, shorter growth duration and a very low flow rate were chosen for CH4. Sample TTGa and TTGc were grown under 1015° C. CH₄ (with a flow rate of 2 sccm) was introduced in the low pressure CVD system for 3 and 5 min respectively. Since the growth rate of graphene on Pd foil under high temperature is high, it is hard to grow thicker transparent graphite under 1015° C. in a controllable way. To grow samples TTG1, TTG2, TTG4, and TTG5, the Pd foils were annealed under 840° C. in gas mixture of 7 sccm H₂ and 50 sccm Ar for 30 min, and then 20 sccm CH₄ was introduced into low pressure CVD system for 3 min, 5 min, 15 min, and 25 min respectively. Table S1 summarizes the growth condition for each sample.

TABLE S1
Summary of CVD growth conditions for
the samples shown in the main text

| Sample | 1LG | TTGa | TTGc | TTG1 | TTG2 | TTG4 | TTG5 |
|---|---|---|---|---|---|---|---|
| Substrate | Cu | Pd | Pd | Pd | Pd | Pd | Pd |
| (foil) | | | | | | | |
| H₂ (sccm) | 7 | 7 | 7 | 7 | 7 | 7 | 7 |
| Ar (sccm) | 0 | 50 | 50 | 50 | 50 | 50 | 50 |
| CH₄ (sccm) | 25 | 2 | 2 | 20 | 20 | 20 | 20 |
| Growth | 1015 | 1015 | 1015 | 840 | 840 | 840 | 840 |
| temper- | | | | | | | |
| ature ° C. | | | | | | | |
| Growth | 30 | 3 | 5 | 3 | 5 | 15 | 25 |
| duration | | | | | | | |
| (min) | | | | | | | |

Each prepared sample was cut into smaller pieces, and these pieces were used for characterizations as well as device fabrication as discussed below.

### S2. Characterization of Graphene and TTG Samples

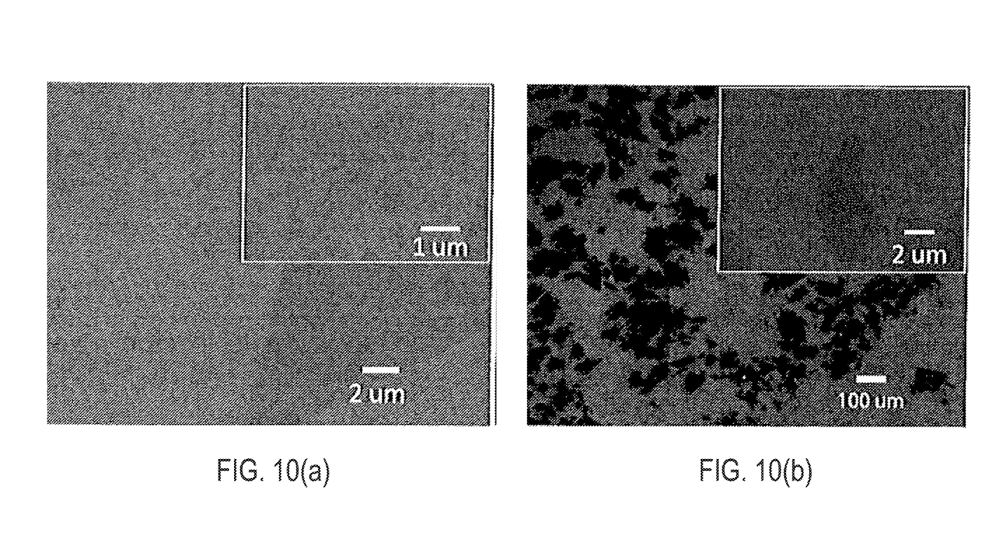

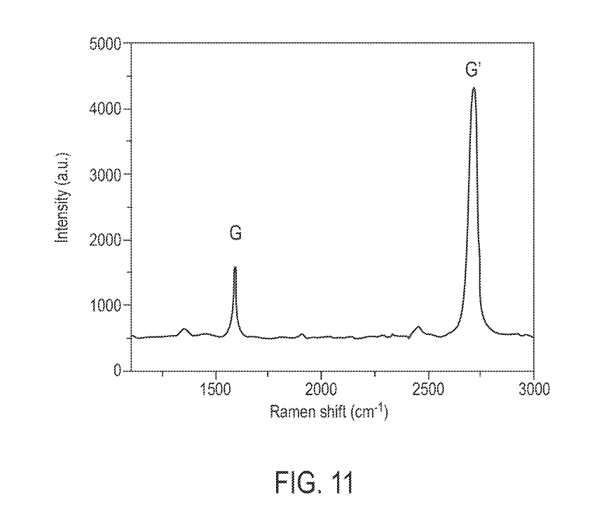

SEM: FIG. 10 shows typical SEM images of the graphene grown on Cu (FIG. 10(a)) and Pd (FIG. 10(b)) substrates. Graphene grown on Cu foils are mostly uniform monolayer, as confirmed by the obtained Raman spectra (see FIG. 11) at several random locations on the samples. By contrast, samples grown on the Pd foil surface were covered with a mixture of thin graphite (darker regions) and multilayer graphene (lighter regions). By changing the growth conditions, the previously mentioned samples with varying relative coverage of the thicker and thinner transparent graphitic areas could be obtained. This resulted in samples with average optical transmittance values ranging from 5%<T<98% (at λ=550 nm) as reported in the main text.

Raman Spectroscopy: FIG. 11 shows a Raman spectrum of a typical monolayer graphene sample. It reveals the spectral features of a G peak at ˜1580 cm⁻¹ and a single-Lorentzian G′ peak around 2706 cm⁻¹, with the relative intensity of the G′ peak with respect to that of the G peak ≧3, which are all signature characteristics of monolayer graphene. With a very small defect-induced D band at ˜1350 cm⁻¹ when measured randomly at various regions of a sample, more than 80% of the spectra showed such a monolayer nature. Depending on the growth condition, the thin transparent graphite samples were found to have varying amounts of monolayer, Bernal multilayer, and turbostratic multilayer graphene regions within the same sample.

Transmittance, sheet resistance, and sample thickness: The optical Transmittance (200 nm<λ<1100 nm) of the samples was measured in a UV-Vis-NIR spectrophotometer (Perkin-Elmer Lambda 35). Two-probe sheet resistance was measured using a Keithley model 2400 Sourcemeter. The average thickness of monolayer graphene samples was found to be about 1 nm (AFM step-height measurement). The thickness of the thin transparent graphite samples were measured using a Dektak profilometer model 3ST. Table S2 summarizes the transmittance at λ=550 nm, the sheet resistance values, and the mean thickness of the graphene and TTG samples.

TABLE S2
Optical transmittance, sheet resistance, and
thickness of the graphene and TTG samples

| Samples | 1LG | 3LG | TGa | TGc | TG1 | TG2 | TG4 | TG5 |
|---|---|---|---|---|---|---|---|---|
| Transmittance | 97.5 | 92 | 62.96 | 56 | 34.22 | 28.69 | 10.62 | 7.40 |
| (λ = 550) (%) | | | | | | | | |
| Sheet resistance | 3000 | 1000 | 861 | 224.9 | 136.37 | 44.71 | 29.85 | 23.09 |
| (Ω□⁻¹) | | | | | | | | |
| Mean thickness (nm) | ~1 | ~3 | 58 | 65 | 83 | 97 | 183 | 223 |

### S3. Device Fabrication

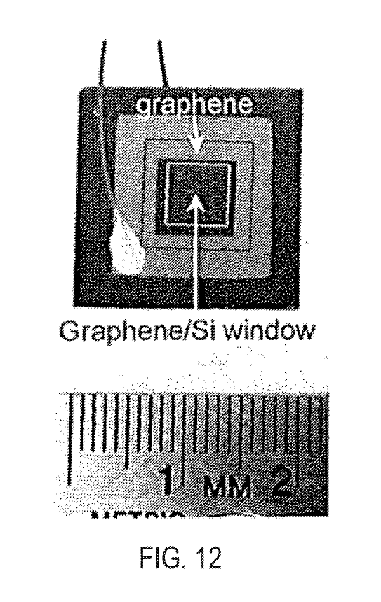

The graphene/Si and TTG/Si heterojunction devices were fabricated on commercially purchased lightly n-doped (resistivity of 1-10 Ω-cm) Si wafers with 400 nm SiO₂ layer. These wafers were diced into square pieces of 2 cm edges for device preparation. First, the front surface of SiO₂/Si wafers were patterned by photolithography and wet-etching of the SiO₂ layer (using a buffered oxide etchant) to prepare square windows (5 mm×5 mm) where the n-doped silicon was exposed. The back surface oxide was also etched out during this process. Next, an e-beam deposition technique was used to deposit rectangular Ti/Au (5 nm/100 nm) film contact pads along the periphery of the Si window on the front (FIG. 12), as well as on the back surface of Si squares, leaving the front windows exposed. To transfer graphene and TTG films onto this window or other substrates, the as-grown graphene and TTG films (on metal foils) were spin-coated with PMMA, and the metal foils were dissolved in a dilute FeCl₃ solution. The PMMA-coated graphene and TTG films were then transferred onto the top of the exposed square window of Si, ensuring that they covered the window and extended onto the Au part of the top contact. After that, the devices were thoroughly rinsed with acetone and isopropanol to remove the PMMA, and dried.

### S4. Responsivity Measurement as a Function of Power

To study the relationship between responsivity (photocurrent and photo-voltage) and incident power, the graphene/Si heterojunction devices (1 LG/Si and 3 LG/Si) were illuminated with a defocused laser (λ=488 nm) with the spot size approximately contained within the device window. The laser power could be controlled within a range of 1 μW<P<10 mW, and was measured using a commercial powermeter (THORLABS PM100A). In darkness and under illumination, the current-voltage (IV) data was collected by using a computer-interfaced Keithley 2400 SourceMeter. The forward bias was defined as positive voltage applied to the graphene and TTG films.

### S5. Responsivity Measurement as a Function of Wavelength

To study the relationship between photocurrent responsivity and wavelength, a commercially purchased UV-vis-NIR spectrophotometer (Perkin-Elmer Lambda 35) was modified to be used as a variable wavelength (190 nm to 1100 nm) monochromatic light source to illuminate the graphene/Si and TTG/Si samples. The incident power at each wavelength was independently measured using the previously mentioned photometer, which varied between 0.3-μW over the entire range of wavelengths. A mount was fabricated to insert the devices (attached to electrical leads) inside the dark optical chamber of the spectrophotometer, and to align them for normal incidence to the monochromatic light. At each wavelength, a complete IV was measured using a Keithley 2400 SourceMeter. As before, the forward bias was defined as positive voltage applied to the graphene and TTG films.

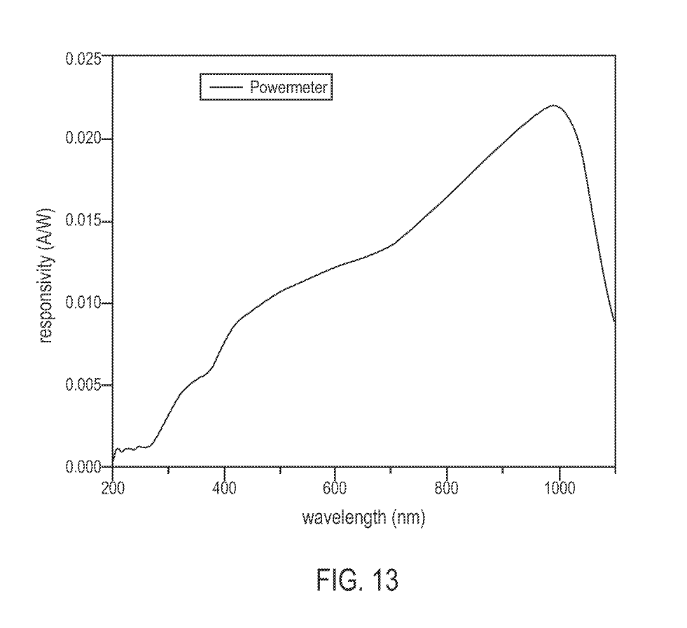

The photocurrent responsivity of the powermeter as provided by the manufacturer is presented in FIG. 13. The comparison of this data with the graphene/Si device demonstrates the superiority of our devices compared to commercial ones.

### S6. Effect of Layer Thickening on the Schottky Barrier Height of the Junctions

The thermal equilibrium barrier height at the interface of graphene and silicon at zero bias may be approximately estimated from the dark current, using the well-known Schottky junction current-voltage relationship,

$$I = {I}_{s} [ exp ( \frac{{eV}_{bias}}{{nk}_{B} T} ) - 1 ] .$$

Here, n is the ideality factor, and Iₛ, the (dark) reverse-saturation current, is given by,

$${I}_{s} = {A}^{*} {AT}^{2} ( \frac{- e {ϕ}_{B}}{{k}_{B} T} ) ,$$

where A is the graphene-Silicon contact area, A* is the effective Richardson's constant, which is 112 Acm⁻²K⁻² for n-Silicon [4], and φB is the Schottky barrier height. From the reverse saturation current, the Schottky barrier height may be directly obtained,

$$i . e . , {ϕ}_{B} = ( \frac{{k}_{B} T}{e} ) ln [ \frac{{A}^{*} {AT}^{2}}{{I}_{s}} ] .$$

Table S3 below lists the Schottky barrier height and for each device.

TABLE S3
Schottky barrier height of the various devices

| Sample | 1LG/Si | 3LG/Si | TTGa/Si | TTGc/Si | TTG1/Si | TTG2/Si | TTG4/Si | TTG5/Si |
|---|---|---|---|---|---|---|---|---|
| φ_{B} (eV) | 0.75 | 0.8 | 0.75 | 0.78 | 0.75 | 0.74 | 0.69 | 0.65 |

### S7. Quality of the C/Si Interface

The method of physically transferring graphene or TTG onto Si without any additional attention to the quality of the interface begs one question, “how good are these interfaces”? One method for ascertaining the high quality interfaces is to estimate the highest value of internal quantum efficiency obtained in our devices. Since the setup in this Example was not equipped to measure the reflectance, R(X), it was not practical to obtain directly the internal quantum efficiency, IQE(λ)=IPC(λ)/[{1-R(λ)]×T(λ)] for each incident wavelength, λ. Instead, the absorption corrected quantum efficiency, ACQE(λ)=IPCE(λ)/T(λ) was obtained, and since IPCE<ACQE<IQE, the ACQE sets a lower limit for the IQE. FIG. 9 shows the IPCE and ACQE of device TTG2/Si, as a function of λ. Between 600 nm-800 nm, the ACQE≧90%, implying that the R(λ)<10% for this wavelength range. While polished Si surfaces have a reflectance >30% in this wavelength range, texturing the surface may bring it down well below 10%.

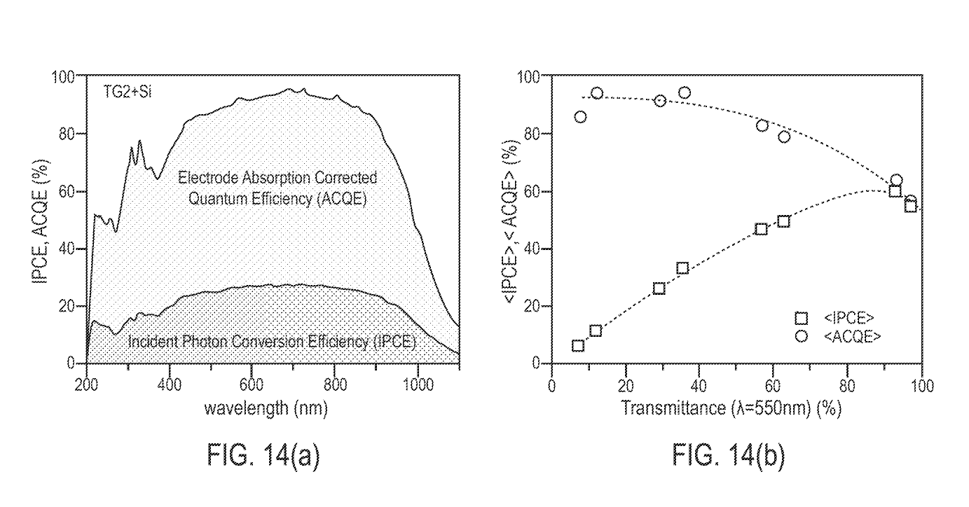

This indicates that the TTG electrodes are also possibly working as a texturing layer that reduces the effective reflectance of the devices. FIG. 14 shows the variation of the <IPCE> and <ACQE> (averaged over λ=400 nm-900 nm) of all the tested devices, as a function of T₅₅₀ₙₘ. It was observed that as the IPCE decreases with decreasing transmittance, the mean ACQE reaches values exceeding 90% in several devices, implying that the IQE values reach near-100% over a broad range of solar-spectrum useful wavelengths.

### S8. Doping

It has been reported that chemical doping may change the Fermi level and hence the carrier concentration of graphene, tuning its electronic properties. 1-Pyrencarboxylic Acid (PCA) and Gold Chloride (AuCl₃) were employed to dope graphene and TTG films by an easy liquid-phase drop-casting method, to further improve their IV in the heterojunction devices. The organic PCA dopant was dissolved in methanol (15 mM), while the AuCl₃ powder was dissolved in Nitromethane (2.5 mM). 4 drops (≈25 μL) of PCA solution was administered onto the top of graphene/Si and TTG/Si devices, followed by about 3 drops (≈20 μL) of AuCl₃ solution, to dramatically improve the final IV characteristic of graphene/Si and TTG/Si heterojunction devices.

Gate modulated transport may directly show how the PCA and AuCl₃ doping on graphene may change their electronic properties. To do this, a back-gated, 3-terminal monolayer graphene device was fabricated on a SiO₂/Si substrate (gate thickness=400 nm of SiO₂) (the Si wafer was used as the back-gate). The gate-modulated channel current in graphene was measured using a Keithley 2612A system SourceMeter.

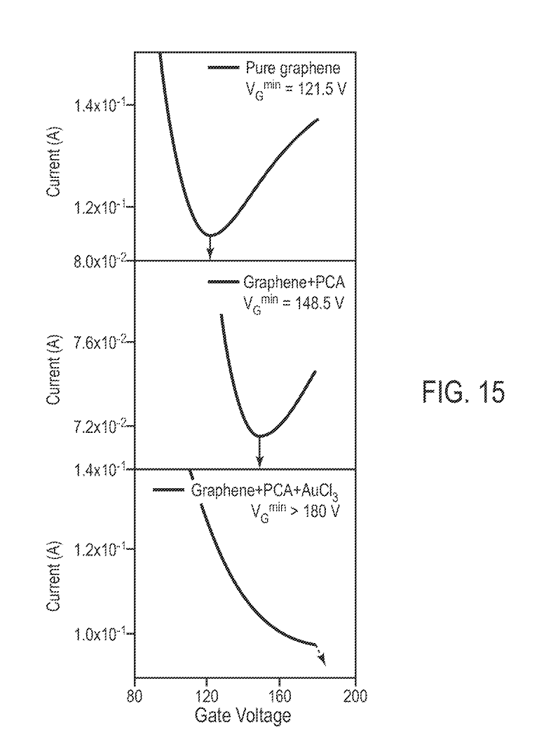

FIGS. 15(1)-11(b) show the I_{D}-V_{G} curves of pristine and doped devices. It may be seen that graphene was originally P-doped during the process of growth and transferring steps, possibly due to residual impurities and/or substrate effects. The charge-neutrality point for pure graphene was at V_{G}^{min}=121.5 V. After dropping 25 μL PCA solution on top of graphene film, V_{G}^{min} shifted to 148.5 V. With further doping with AuCl₃ on graphene, V_{G}^{min} goes above 180 V (the gate oxide becomes unstable beyond this voltage). This demonstrated increased p-type doping of graphene associated with PCA and AuCl₃.

### S9. Effect of Doping on the TTGc/Si Device

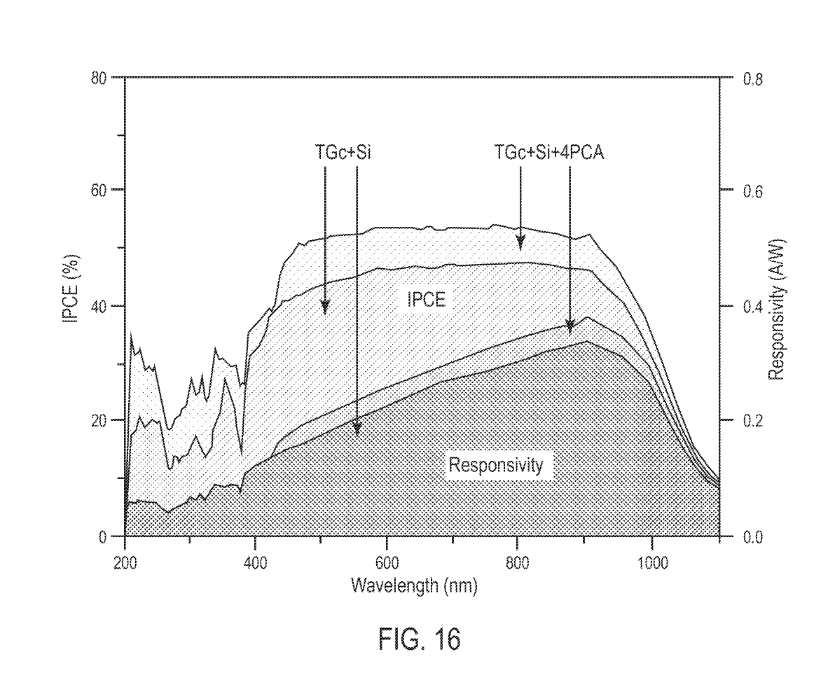

FIG. 16 shows the effect of doping on the best photovoltaic device, TTGc/Si. The decrease of responsivity in UV region is due to the strong absorption of PCA at these wavelengths. The broadband increase in IPCE and responsivity over nearly the entire solar-spectrum-friendly wavelengths helps it to achieve the high PCE reported in the main text.

### S10. Effect of Doping on the Schottky Barrier Height of the Junction

Table S4 lists the Schottky-barrier height for device TTGc/Si without or with different dopants. It may be seen that the Schottky barrier height increased after dopants were added on TTGc/Si device, as expected (see Example 1).

TABLE S4
Effect of doping on the Schottky barrier height of the junction

| | | | 3AuCl3 + | 6AuCl3 + |
|---|---|---|---|---|
| | | 4PCA + | 4PCA + | 4PCA + |
| Sample | TTGc/Si | TTGc/Si | TTGc/Si | TTGc/Si |
| φ_{B} (eV) | 0.78 | 0.82 | 0.82 | 0.81 |

### Additional Notes

All literature and similar material cited in this application, including, but not limited to, patents, patent applications, articles, books, treatises, and web pages, regardless of the format of such literature and similar materials, are expressly incorporated by reference in their entirety. In the event that one or more of the incorporated literature and similar materials differs from or contradicts this application, including but not limited to defined terms, term usage, described techniques, or the like, this application controls.

While the present teachings have been described in conjunction with various embodiments and examples, it is not intended that the present teachings be limited to such embodiments or examples. On the contrary, the present teachings encompass various alternatives, modifications, and equivalents, as will be appreciated by those of skill in the art.

While various inventive embodiments have been described and illustrated herein, those of ordinary skill in the art will readily envision a variety of other means and/or structures for performing the function and/or obtaining the results and/or one or more of the advantages described herein, and each of such variations and/or modifications is deemed to be within the scope of the inventive embodiments described herein. More generally, those skilled in the art will readily appreciate that all parameters, dimensions, materials, and configurations described herein are meant to be exemplary and that the actual parameters, dimensions, materials, and/or configurations will depend upon the specific application or applications for which the inventive teachings is/are used. Those skilled in the art will recognize many equivalents to the specific inventive embodiments described herein. It is, therefore, to be understood that the foregoing embodiments are presented by way of example only and that, within the scope of the appended claims and equivalents thereto, inventive embodiments may be practiced otherwise than as specifically described and claimed. Inventive embodiments of the present disclosure are directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the inventive scope of the present disclosure.

The above-described embodiments of the invention may be implemented in any of numerous ways. For example, some embodiments may be implemented using hardware, software or a combination thereof. When any aspect of an embodiment is implemented at least in part in software, the software code may be executed on any suitable processor or collection of processors, whether provided in a single computer or distributed among multiple computers.

Also, the technology described herein may be embodied as a method, of which at least one example has been provided. The acts performed as part of the method may be ordered in any suitable way. Accordingly, embodiments may be constructed in which acts are performed in an order different than illustrated, which may include performing some acts simultaneously, even though shown as sequential acts in illustrative embodiments.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.” Any ranges cited herein are inclusive.

The terms “substantially” and “about” used throughout this Specification are used to describe and account for small fluctuations. For example, they may refer to less than or equal to ±5%, such as less than or equal to ±2%, such as less than or equal to ±1%, such as less than or equal to ±0.5%, such as less than or equal to ±0.2%, such as less than or equal to ±0.1%, such as less than or equal to ±0.05%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” may refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified. Thus, as a non-limiting example, “at least one of A and B” (or, equivalently, “at least one of A or B,” or, equivalently “at least one of A and/or B”) may refer, in one embodiment, to at least one, optionally including more than one, A, with no B present (and optionally including elements other than B); in another embodiment, to at least one, optionally including more than one, B, with no A present (and optionally including elements other than A); in yet another embodiment, to at least one, optionally including more than one, A, and at least one, optionally including more than one, B (and optionally including other elements); etc.

In the claims, as well as in the specification above, all transitional phrases such as “comprising,” “including,” “carrying,” “having,” “containing,” “involving,” “holding,” “composed of,” and the like are to be understood to be open-ended, i.e., to mean including but not limited to. Only the transitional phrases “consisting of” and “consisting essentially of” shall be closed or semi-closed transitional phrases, respectively, as set forth in the United States Patent Office Manual of Patent Examining Procedures, Section 2111.03.

The claims should not be read as limited to the described order or elements unless stated to that effect. It should be understood that various changes in form and detail may be made by one of ordinary skill in the art without departing from the spirit and scope of the appended claims. All embodiments that come within the spirit and scope of the following claims and equivalents thereto are claimed.

What is claimed:

1. A method for operating a photodiode device comprising:
providing a photodiode device comprising:
at least one layer of an n-doped semiconductor material;
two portions of a dielectric material separately disposed over separate regions of the at least one layer of the n-doped semiconductor material;
at least one monolayer of a carbon-based material disposed between the two portions of dielectric material and over the at least one layer of the n-doped semiconductor material;
two terminal electrodes, each electrode disposed in electrical communication with a respective one of the portions of dielectric material; and
a gate electrode in electrical communication with the at least one layer of the n-doped semiconductor material;
applying a voltage across the gate electrode and one of the two terminal electrodes; and
exposing the photodiode device to electromagnetic radiation;
wherein a measure of an electrical property of the photodiode device provides a measure of the electromagnetic radiation incident on the photodiode device.

2. The method of claim 1, further comprising growing the carbon-based material using at least chemical vapor deposition.

3. The method of claim 1, further comprising disposing the carbon-based material over the at least one layer of the n-doped semiconductor material by transferring the carbon-based material onto a portion of a surface of the at least one layer of the n-doped semiconductor material.

4. The method of claim 1, further comprising disposing the carbon-based material over the at least one layer of the n-doped semiconductor material by transfer printing a monolayer of the carbon-based material onto a portion of a surface of the at least one layer of the n-doped semiconductor material.

5. The method of claim 1, wherein the n-doped semiconductor material comprises silicon.

6. The method of claim 1, wherein the carbon-based material comprises graphene.

7. The method of claim 1, wherein the carbon-based material is p-doped.

8. The method of claim 1, further comprising doping the carbon-based material using at least one of 1-pyrenecarboxylic acid and AuCl₃.

9. The method of claim 1, further comprising increasing a thickness of the carbon-based material.

10. The method of claim 1, further comprising increasing a thickness of the carbon-based material by stacking a plurality of monolayers comprising the carbon-based material.

11. A method for operating a photodiode device comprising:
providing a photodiode device comprising:
at least one layer of an n-doped semiconductor material;
two portions of a dielectric material separately disposed over two separate regions of the at least one layer of the n-doped semiconductor material;
a carbon-based material disposed between the two portions of the dielectric material and over the at least one layer of the n-doped semiconductor material;
two terminal electrodes, each electrode disposed in electrical communication with a respective one of the two portions of dielectric material; and
a gate electrode in electrical communication with the at least one layer of the n-doped semiconductor material;
applying a voltage across the two terminal electrodes; and
exposing the photodiode device to electromagnetic radiation,
wherein a measure of an electrical property of the photodiode device provides a measure of the electromagnetic radiation incident on the photodiode device.

12. The method of claim 11, further comprising growing the carbon-based material using at least chemical vapor deposition.

13. The method of claim 11, further comprising disposing the carbon-based material over the at least one layer of the n-doped semiconductor material by transferring the carbon-based material onto a portion of a surface of the at least one layer of the n-doped semiconductor material.

14. The method of claim 11, further comprising doping the carbon-based material using at least one of 1-pyrenecarboxylic acid and AuCl₃.

15. The method of claim 11, further comprising increasing a thickness of the carbon-based material.

16. A method for operating a photodiode device comprising:
providing a photodiode device comprising:
at least one layer of an n-doped semiconductor material;
two portions of a dielectric material separately disposed over separate regions of the at least one layer of the n-doped semiconductor material;
a carbon-based semiconducting material disposed between the two portions of dielectric material and over the at least one layer of the n-doped semiconductor material;
two terminal electrodes, each electrode disposed in electrical communication with a respective one of the portions of dielectric material; and
a gate electrode in electrical communication with the at least one layer of the n-doped semiconductor material;
applying a voltage across the gate electrode and one of the two terminal electrodes;
exposing the photodiode device to electromagnetic radiation;
measuring an electrical property of the photodiode device to provide a measure of the electromagnetic radiation incident on the photodiode device; and
applying the voltage across the two terminal electrodes if the measure of the electromagnetic radiation incident on the photodiode device falls below a predetermined threshold value.

17. The method of claim 16, further comprising:
providing a second photodiode with an active region of reduced lateral dimensions when the measure of the electromagnetic radiation incident on the photodiode device falls below a predetermined threshold value; and
exposing the second photodiode to the electromagnetic radiation,
wherein a measure of an electrical property of the second photodiode device provides a measure of the electromagnetic radiation incident on second the photodiode device.

18. The method of claim 16, further comprising disposing the carbon-based material over the at least one layer of the n-doped semiconductor material by transfer printing a monolayer of the carbon-based material onto a portion of a surface of the at least one layer of the n-doped semiconductor material.

19. The method of claim 16, further comprising doping the carbon-based material using at least one of 1-pyrenecarboxylic acid and AuCl₃.

20. The method of claim 16, further comprising increasing a thickness of the carbon-based material.
